(19) United States
(12) Patent Application Publication
(10) Pub. No.: US 2022/0147191 A1
(43) Pub. Date: May 12, 2022

(54) INPUT DETECTION SYSTEM AND INPUT SUPPORT DEVICE

(71) Applicant: Japan Display Inc., Tokyo (JP)

(72) Inventors: Yuto KAKINOKI, Tokyo (JP); Makoto HAYASHI, Tokyo (JP); Takaaki KONO, Tokyo (JP)

(21) Appl. No.: 17/511,940

(22) Filed: Oct. 27, 2021

(30) Foreign Application Priority Data
Nov. 12, 2020 (JP) 2020-188781

(51) Int. Cl. G06F 3/044; H03K 17/96

(52) U.S. Cl. CPC G06F 3/0446; G06F 3/0443; H03K 2017/9602; H03K 17/962; G06F 3/0448

(57) ABSTRACT

An input detection system includes a plurality of electrodes arrayed in a detection region, and an input support device including an LC circuit, a first electrode coupled to one end side of the LC circuit, a second electrode coupled to another end side of the LC circuit, and a housing accommodating therein at least the LC circuit. The input support device is disposed overlapping with a plurality of the electrodes, the housing is a conductor, the LC circuit includes a first capacitor and a second capacitor coupled in series between the one end side and the other end side of the LC circuit, and a coupling portion between the first capacitor and the second capacitor is coupled to the housing.

### CROSS-REFERENCE TO RELATED APPLICATION

This application claims the benefit of priority from Japanese Patent Application No. 2020-188781 filed on Nov. 12, 2020, the entire contents of which are incorporated herein by reference.

### BACKGROUND

### 1. Technical Field

The present disclosure relates to an input detection system and an input support device.

### 2. Description of the Related Art

Japanese Patent No. 6342105 and Japanese Patent No. 6532631 describe an input support device (described as an operation knob or a knob in Japanese Patent Nos. 6342105 and 6532631) that is placed on a touch panel configured to detect change in electrostatic capacitance or change in a contact region and supports input operations through the touch panel. One known method of detecting an input support device is to use the resonance of a resonance circuit installed in the input support device to detect the input support device.

In an input detection system using such an input support device, the resonant frequency of the resonance circuit may change due to the parasitic capacitance between the input support device and the outside, for example, the parasitic capacitance formed between a housing and a finger or a palm of an operator.

### SUMMARY

An input detection system according to an embodiment of the present disclosure includes a plurality of electrodes arrayed in a detection region, and an input support device including an LC circuit, a first electrode coupled to one end side of the LC circuit, a second electrode coupled to another end side of the LC circuit, and a housing accommodating therein at least the LC circuit. The input support device is disposed overlapping with a plurality of the electrodes, the housing is a conductor, the LC circuit includes a first capacitor and a second capacitor coupled in series between the one end side and the other end side of the LC circuit, and a coupling portion between the first capacitor and the second capacitor is coupled to the housing.

An input support device according to an embodiment of the present disclosure includes an LC circuit, a first electrode coupled to one end side of the LC circuit, a second electrode coupled to another end side of the LC circuit, and a housing accommodating therein at least the LC circuit. The housing is a conductor, the LC circuit includes a first capacitor and a second capacitor coupled in series between the one end side and the other end side of the LC circuit, and a coupling portion between the first capacitor and the second capacitor is coupled to the housing.

### BRIEF DESCRIPTION OF THE DRAWINGS

FIG. 1 is a perspective view schematically illustrating an input detection system according to a first embodiment;

FIG. 2 is a cross-sectional view cut along line II-II′ in FIG. 1;

FIG. 3 is a cross-sectional view illustrating a schematic cross-sectional configuration of a display device;

FIG. 4 is a circuit diagram illustrating a pixel array of a display region;

FIG. 5 is a plan view schematically illustrating an array substrate included in the display device;

FIG. 6 is a cross-sectional view cut along line VI-VI′ in FIG. 2;

FIG. 7 is a descriptive view for explaining a method for detecting an input support device;

FIG. 8 is a timing waveform chart for explaining the method for detecting the input support device;

FIG. 9 is a flowchart for explaining a detection method in the input detection system;

FIG. 10 is a descriptive view for explaining an input support device according to a first modification;

FIG. 11 is a plan view schematically illustrating an input support device according to a second modification; and

FIG. 12 is a plan view schematically illustrating an array substrate in an input detection system according to a second embodiment.

### DETAILED DESCRIPTION

Modes for carrying out the present disclosure (embodiments) will be described in detail with reference to the drawings. Contents described in the following embodiment do not limit the present disclosure. Components described below include those that can be easily assumed by those skilled in the art and substantially the same components. Furthermore, the components described below can be appropriately combined. What is disclosed herein is merely an example, and it is needless to say that appropriate modifications within the gist of the present disclosure at which those skilled in the art can easily arrive are encompassed in the scope of the present disclosure. In the drawings, widths, thicknesses, shapes, and the like of the components can be schematically illustrated in comparison with actual modes for clearer explanation. They are, however, merely examples and do not limit interpretation of the present disclosure. In the present disclosure and the drawings, the same reference numerals denote components similar to those described before with reference to the drawing that has already been referred, and detail explanation thereof can be appropriately omitted.

In the present specification and the scope of the claims, when a mode in which a second structure is arranged above a first structure is represented, simple expression “above” includes both the case in which the second structure is arranged immediately above the first structure in a manner contacting the first structure, and the case in which the second structure is arranged above the first structure with still a third structure interposed therebetween, unless otherwise specified.

### First Embodiment

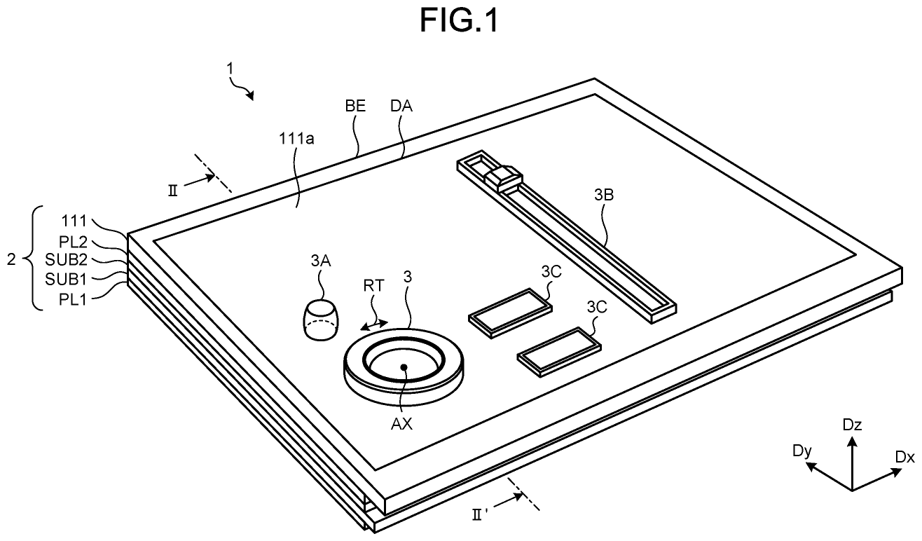

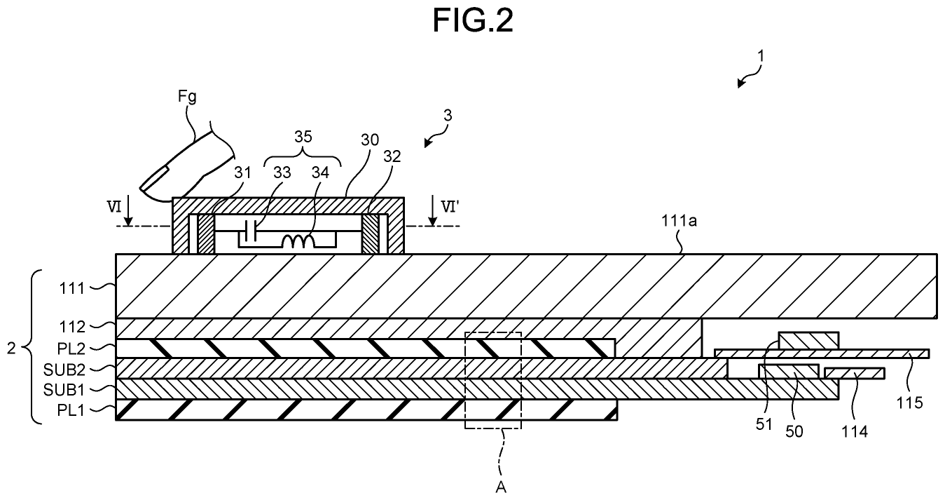

FIG. 1 is a perspective view schematically illustrating an input detection system according to a first embodiment. FIG. 2 is a cross-sectional view cut along line II-II′ in FIG. 1. As illustrated in FIG. 1 and FIG. 2, an input detection system 1 includes a display device 2 and an input support device (input device) 3.

One direction of a plane (upper surface 111a) of the display device 2 is a first direction Dx, and a direction orthogonal to the first direction Dx is a second direction Dy. The second direction Dy is not limited thereto and may intersect with the first direction Dx at an angle other than 90°. A third direction Dz orthogonal to the first direction Dx and the second direction Dy corresponds to the thickness direction of an array substrate SUB1.

As illustrated in FIG. 1, the display device 2 includes the array substrate SUB1, a counter substrate SUB2, a first polarizing plate PL1, a second polarizing plate PL2, a cover member 111, and an adhesive layer 112 (see FIG. 2). The first polarizing plate PL1, the array substrate SUB1, the counter substrate SUB2, the second polarizing plate PL2, the adhesive layer 112, and the cover member 111 are stacked in this order in the third direction Dz.

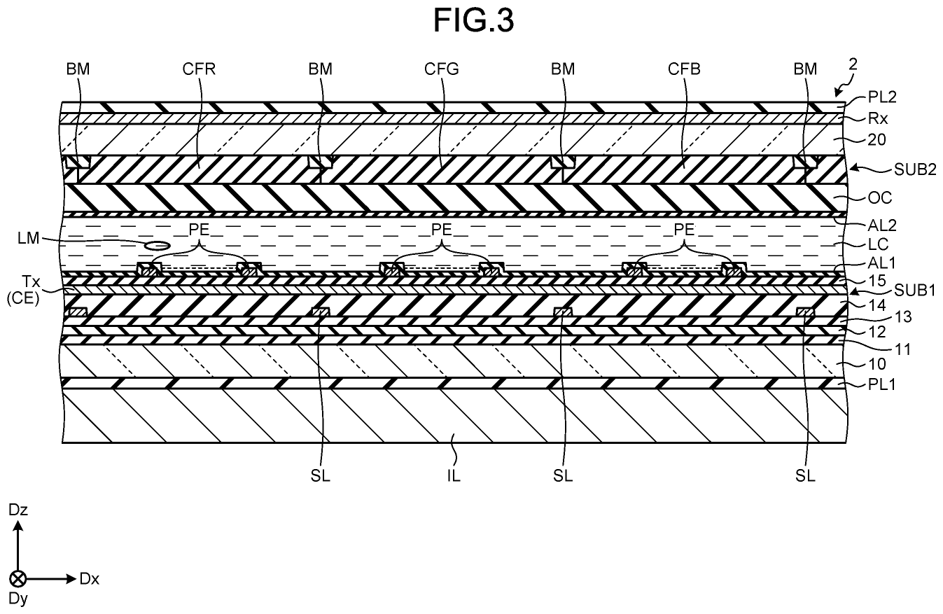

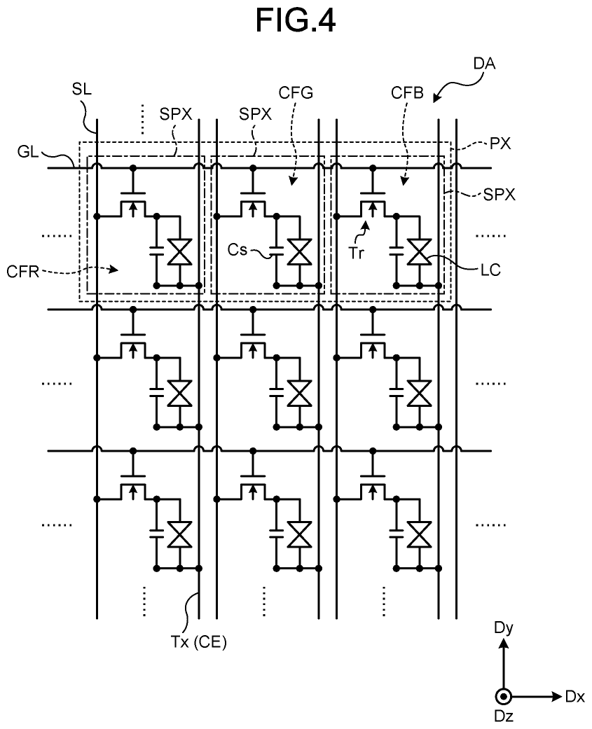

The array substrate SUB1 is a drive circuit substrate for driving a plurality of pixels PX. The array substrate SUB1 includes a first substrate 10 as a base body. The array substrate SUB1 includes switching elements Tr provided on the first substrate 10 and various wiring lines such as scan lines GL and pixel signal lines SL (see FIG. 4). The counter substrate SUB2 is provided so as to face the array substrate SUB1 and includes a second substrate 20 as a base body. The counter substrate SUB2 includes color filters CF and a light shielding layer BM (see FIG. 3) provided on the second substrate 20. The first substrate 10 and the second substrate 20 are made of a material having a light transmitting property, such as a glass substrate and a resin substrate.

The length of the array substrate SUB1 in the second direction Dy is larger than the length of the counter substrate SUB2 in the second direction Dy. As illustrated in FIG. 1, the array substrate SUB1 (first substrate 10) has a portion (protruding portion) projecting to the outer side of the counter substrate SUB2 (second substrate 20). The lengths of the array substrate SUB1 and the counter substrate SUB2 in the second direction Dy are smaller than the lengths thereof in the first direction Dx. The lengths are not limited to the ones being set in this manner, and the lengths of the array substrate SUB1 and the counter substrate SUB2 in the second direction Dy may be larger than the lengths thereof in the first direction Dx.

As illustrated in FIG. 1, a peripheral region BE is provided on the outer side of a display region DA in the display device 2. The display region DA is formed to have a square shape but the outer shape of the display region DA is not limited thereto. For example, the display region DA may have a substantially square shape with curved corners or may have a cutout. Alternatively, the display region DA may have another polygonal shape or another shape such as a circular shape and an elliptic shape.

The display region DA is a region for displaying an image and is a region in which the pixels PX are provided. The peripheral region BE indicates a region on the inner side of the outer circumference of the array substrate SUB1 and on the outer side of the display region DA. The peripheral region BE may have a frame shape surrounding the display region DA, and in this case, the peripheral region BE can also be referred to as a frame region.

As illustrated in FIG. 2, a display integrated circuit (IC) 50 and a wiring substrate 114 are coupled to the protruding portion of the array substrate SUB1. The display IC 50 includes a control circuit that controls display and touch detection of the display device 2. The display IC 50 is not limited to this example and may be mounted on the wiring substrate 114. Arrangement of the display IC 50 is not limited thereto, and the display IC 50 may be provided above a control substrate or a flexible substrate outside the module, for example.

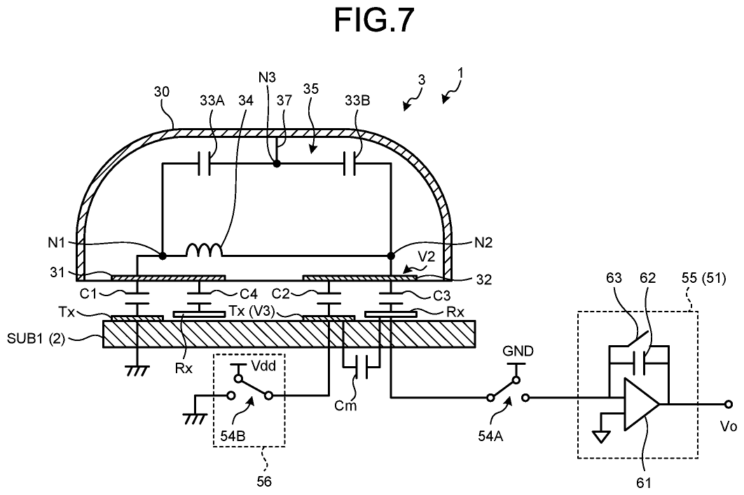

A wiring substrate 115 is coupled to the counter substrate SUB2. A detection IC 51 is mounted on the wiring substrate 115. The detection IC 51 includes a detection circuit 55 (see FIG. 7), and a detection signal Vdet is supplied from a detection electrode Rx. Based on the detection signal Vdet, the detection IC 51 can detect an object to be detected such as a finger Fg or the input support device 3. Arrangement of the detection IC 51 is not limited thereto, and the detection IC 51 may be provided above a control substrate or a flexible substrate outside the module, for example.

The wiring substrate 114 and the wiring substrate 115 are configured by flexible printed circuits (FPCs), for example. The wiring substrate 114 is coupled to a plurality of terminals of the first substrate 10. The wiring substrate 115 is coupled to a plurality of terminals of the second substrate 20.

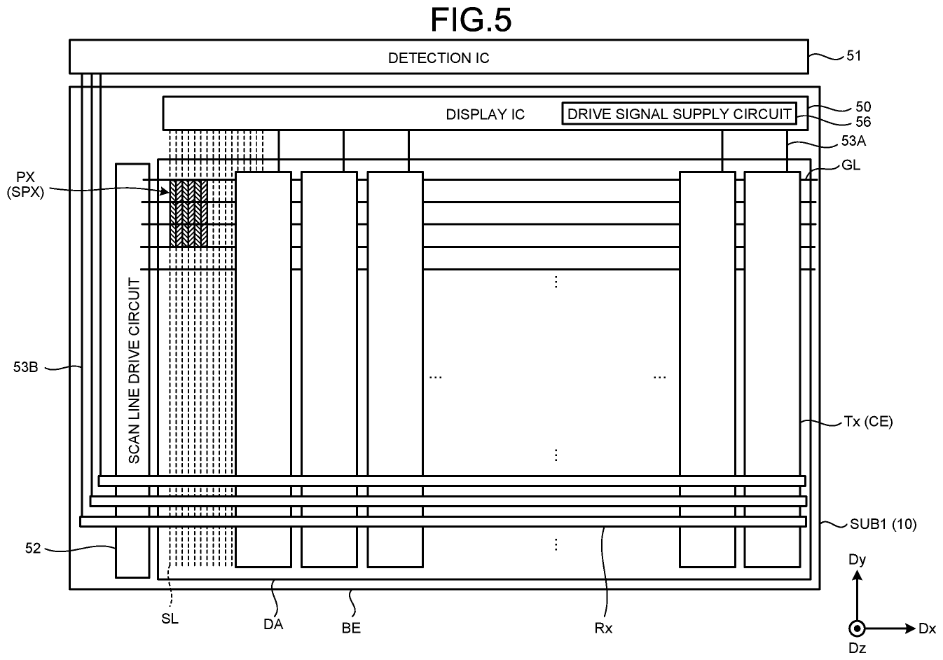

As illustrated in FIG. 1 and FIG. 2, the input support device 3 is arranged (mounted) on the upper surface 111a of the cover member 111 for use. A user operates the input support device 3 arranged above the display device 2 to perform an input operation on the display device 2. The input support device 3 is, for example, a rotary knob and has an annular shape in a plan view when seen from the upper surface 111a of the display device 2. The display device 2 can detect a position of the input support device 3 in a plane and a rotation operation RT about a rotating axis AX. That is to say, in the embodiment, the display region DA is a region in which a plurality of drive electrodes Tx and a plurality of detection electrodes Rx (see FIG. 5) are provided, and serves also as a detection region.

As illustrated in FIG. 2, the input support device 3 includes a housing 30, a first electrode 31, a second electrode 32, and an LC circuit 35. The housing 30 is formed by a conductor made of a metal material, for example, and is a hollow member in which a space is provided. The first electrode 31, the second electrode 32 and the LC circuit 35 are provided in the housing 30. The LC circuit 35 configures an LC resonance circuit in which a capacitor 33 and an inductor 34 are coupled in parallel. The first electrode 31 is coupled to one end side of the LC circuit 35 (a coupling portion N1 (see FIG. 7) of the capacitor 33 and the inductor 34 on their one end sides). The second electrode 32 is coupled to the other end side of the LC circuit 35 (a coupling portion N2 (see FIG. 7) of the capacitor 33 and the inductor 34 on their other end sides). The display device 2 can detect positions of the first electrode 31 and the second electrode 32 using LC resonance of the LC circuit 35.

In the following explanation, the housing 30 has a circular shape in a plan view with no through-hole in order to schematically illustrate the LC circuit 35. The shape of the housing 30 can, however, be appropriately modified, and the housing 30 may have an annular shape with a through-hole formed in a region overlapping with the rotating axis AX as illustrated in FIG. 1. The detailed coupling configuration of the LC circuit 35 will be described later.

FIG. 1 illustrates a plurality of input support devices 3A, 3B, and 3C as other examples of the input support device 3. The input support device 3A is a rotary knob and is formed into a tab shape having a smaller plane (diameter) than that of the input support device 3. The input support device 3B is a slider, and an input operation can be performed by displacement of a tab thereof in a plane. The input support device 3B has a bar-like shape in a plan view. The input support device 3C is a button or an input key, and an input operation can be performed by touching the input support device 3C or performing a press-in operation thereon. The input detection system 1 is not limited to the configuration in which all of the input support devices 3, 3A, 3B, and 3C are mounted, and it is sufficient that at least equal to or more than one of the input support devices 3, 3A, 3B, and 3C is provided. Hereinafter, the input support device 3 is described. Explanation of the input support device 3 can be applied also to the other input support devices 3A, 3B, and 3C.

FIG. 3 is a cross-sectional view illustrating the schematic cross-sectional configuration of the display device. FIG. 3 is a cross-sectional view of a part surrounded by a region A in FIG. 2, for example. As illustrated in FIG. 3, the display device 2 further includes an illumination device IL. The counter substrate SUB2 is arranged so as to face the surface of the array substrate SUB1 in the vertical direction. A liquid crystal layer LC is provided between the array substrate SUB1 and the counter substrate SUB2. The liquid crystal layer LC as a display function layer is arranged between the first substrate 10 and the second substrate 20. The illumination device IL, the first polarizing plate PL1, the array substrate SUB1, the counter substrate SUB2, and the second polarizing plate PL2 are stacked in this order in the third direction Dz.

The array substrate SUB1 faces the illumination device IL, and the counter substrate SUB2 is located on the display surface side. The illumination device IL emits light toward the array substrate SUB1. For example, a sidelight-type backlight or a direct-type backlight can be applied as the illumination device IL. Although various types of the illumination device IL can be applied, explanation of the detail configurations thereof is omitted.

An optical element including the first polarizing plate PL1 faces the first substrate 10. To be more specific, the first polarizing plate PL1 is arranged on the outer surface of the first substrate 10 or on the surface thereof facing the illumination device IL. An optical element including the second polarizing plate PL2 faces the second substrate 20. To be more specific, the second polarizing plate PL2 is arranged on the outer surface of the second substrate 20 or on the surface thereof on the observation position side. A first polarization axis of the first polarizing plate PL1 and a second polarization axis of the second polarizing plate PL2 have a crossed nicol positional relation in an X-Y plane, for example. The optical elements including the first polarizing plate PL1 and the second polarizing plate PL2 may include another optical function element such as a phase difference plate.

The array substrate SUB1 includes insulating films 11, 12, 13, 14, and 15, the pixel signal lines SL, pixel electrodes PE, the drive electrodes Tx (common electrodes CE), and a first orientation film AL1 on the side of the first substrate 10 that faces the counter substrate SUB2.

In the present specification, the direction toward the second substrate 20 from the first substrate 10 in the direction perpendicular to the first substrate 10 is an “upper-side direction” or simply an “upward direction”. The direction toward the first substrate 10 from the second substrate 20 is a “lower-side direction” or simply a “downward direction”. The expression “plan view” indicates a positional relation when seen from the direction perpendicular to the first substrate 10.

The insulating film 11 is provided above the first substrate 10. The insulating films 11, 12, and 13, and the insulating film 15 are inorganic insulating films made of, for example, an inorganic material having a light transmitting property, such as silicon oxide and silicon nitride.

The insulating film 12 is provided above the insulating film 11. The insulating film 13 is provided above the insulating film 12. The pixel signal lines SL are provided above the insulating film 13. The insulating film 14 is provided above the insulating film 13 and covers the pixel signal lines SL. The insulating film 14 is made of a resin material having a light transmitting property and has a film thickness that is thicker than those of the other insulating films made of the inorganic material. Although not illustrated in FIG. 3, the scan lines GL are provided above the insulating film 12, for example.

The drive electrodes Tx are provided above the insulating film 14. The drive electrodes Tx are provided in the display region DA and are divided into a plurality of parts by slits. The drive electrodes Tx are covered with the insulating film 15. The drive electrodes Tx serve as the drive electrodes Tx for touch detection and the common electrodes CE in display.

The pixel electrodes PE are provided above the insulating film 15 and face the drive electrodes Tx with the insulating film 15 interposed therebetween. The pixel electrodes PE and the drive electrodes Tx are made of, for example, a conductive material having a light transmitting property, such as indium tin oxide (ITO) or indium zinc oxide (IZO). The first orientation film AL1 covers the pixel electrodes PE and the insulating film 15.

The counter substrate SUB2 includes the light shielding layer BM, color filters CFR, CFG, and CFB, an overcoat layer OC, a second orientation film AL2 and the like on the side of the second substrate 20 that faces the array substrate SUB1. The counter substrate SUB2 includes the detection electrodes Rx and the second polarizing plate PL2 on the side of the second substrate 20 that is opposite to the array substrate SUB1.

The light shielding layer BM is located on the second substrate 20 on the side facing the array substrate SUB1 in the display region DA. The light shielding layer BM defines openings that respectively face the pixel electrodes PE. The pixel electrodes PE are partitioned for the respective openings of the pixels PX. The light shielding layer BM is made of a resin material in black color or a metal material having a light shielding property.

The color filters CFR, CFG, and CFB are located on the second substrate 20 on the side facing the array substrate SUB1, and end portions thereof overlap with the light shielding layer BM. As an example, the color filters CFR, CFG, and CFB are made of a resin material colored in red, green, and blue, respectively.

The overcoat layer OC covers the color filters CFR, CFG, and CFB. The overcoat layer OC is made of a resin material having a light transmitting property. The second orientation film AL2 covers the overcoat layer OC. The first orientation film AL1 and the second orientation film AL2 are made of, for example, a material exhibiting horizontal orientation performance.

The detection electrodes Rx are provided above the second substrate 20. The detection electrodes Rx are, for example, metal wiring formed of a conductive material. The detection electrodes Rx may be made of a conductive material having a light transmitting property, such as ITO.

The array substrate SUB1 and the counter substrate SUB2 are arranged such that the first orientation film AL1 and the second orientation film AL2 face each other. The liquid crystal layer LC is enclosed into between the first orientation film AL1 and the second orientation film AL2. The liquid crystal layer LC is made of a negative liquid crystal material having a negative dielectric anisotropy or a positive liquid crystal material having a positive dielectric anisotropy.

For example, when the liquid crystal layer LC is made of the negative liquid crystal material and a state in which no voltage is applied to the liquid crystal layer LC is established, liquid crystal molecules LM are initially oriented in such a direction that long axes thereof are along the first direction Dx in the X-Y plane. On the other hand, in a state in which the voltage is applied to the liquid crystal layer LC, that is, in an ON state in which an electric field is formed between the pixel electrodes PE and the drive electrodes Tx, the liquid crystal molecules LM receive influences of the electric field and orientation states thereof are changed. In the ON state, a polarization state of incident linearly polarized light is changed in accordance with the orientation states of the liquid crystal molecules LM when the light passes through the liquid crystal layer LC.

FIG. 4 is a circuit diagram illustrating pixel array of the display region. The switching elements Tr of respective sub pixels SPX, the pixel signal lines SL, and the scan lines GL illustrated in FIG. 4, and the like are formed on the array substrate SUB1. The pixel signal lines SL extend in the second direction Dy. The pixel signal lines SL are wiring lines for supplying pixel signals to the pixel electrodes PE (see FIG. 3). The scan lines GL extend in the first direction Dx. The scan lines GL are wiring lines for supplying drive signals (scan signals) for driving the switching elements Tr.

Each pixel PX includes the sub pixels SPX. Each sub pixel SPX includes the switching element Tr and capacitance of the liquid crystal layer LC. The switching element Tr is formed by a thin film transistor and, in this example, is formed by an n-channel metal oxide semiconductor (MOS) TFT. The insulating film 15 is provided between the pixel electrodes PE and the drive electrodes Tx illustrated in FIG. 3, and they form holding capacitance Cs illustrated in FIG. 4.

Color regions colored in three colors of red (R), green (G), and blue (B), for example, are periodically arrayed as the color filters CFR, CFG, and CFB. The color regions of the three colors of R, G, and B as one set are made to respectively correspond to the sub pixels SPX. A set of sub pixels SPX corresponding to the color regions of the three colors configures a pixel PX. The color filters may include color regions of equal to or more than four colors. In this case, the pixel PX may include equal to or more than four sub pixels SPX.

FIG. 5 is a plan view schematically illustrating the array substrate included in the display device. FIG. 5 schematically illustrates some of the detection electrodes Rx provided on the counter substrate SUB2 in order to explain the relation between the drive electrodes Tx and the detection electrodes Rx. As illustrated in FIG. 5, the pixels PX (sub pixels SPX) are arrayed in a matrix with a row-column configuration in the display region DA. The pixel signal lines SL and the scan lines GL are provided correspondingly to the pixel electrodes PE and the switching elements Tr that the sub pixels SPX have. The pixel signal lines SL are coupled to the control circuit such as the display IC 50 provided in the peripheral region BE. A scan line drive circuit 52 is provided in a region extending along the second direction Dy in the peripheral region BE. The scan lines GL are coupled to the scan line drive circuit 52. The scan line drive circuit 52 supplies the scan signal for driving the switching elements Tr of the pixels PX (sub pixels SPX) to the scan lines GL.

The drive electrodes Tx extend in the second direction Dy and are aligned in the first direction Dx. The drive electrodes Tx are coupled to the display IC 50 through coupling wiring lines 53A. The detection electrodes Rx extend in the first direction Dx and are aligned in the second direction Dy. The detection electrodes Rx are coupled to the detection IC 51 through coupling wiring lines 53B. The drive electrodes Tx and the detection electrodes Rx intersect with each other in a plan view. Electrostatic capacitances are formed in intersecting portions between the drive electrodes Tx and the detection electrodes Rx. The detection IC 51 can detect the object to be detected based on the detection signals Vdet that are output in accordance with change in mutual electrostatic capacitances between the drive electrodes Tx and the detection electrodes Rx.

Although FIG. 5 illustrates only some drive electrodes Tx, some detection electrodes Rx, and some pixels PX (sub pixels SPX) in order to make the drawing easy to view, the drive electrodes Tx, the detection electrodes Rx, and the pixels PX are arranged on the entire display region DA. That is, the pixels PX are arranged so as to overlap with one drive electrode Tx. One drive electrode Tx is arranged so as to overlap with the pixel signal lines SL.

The drive electrodes Tx serve as the common electrodes CE in display and as the drive electrodes Tx for detecting an object to be detected such as a finger Fg and the input support device 3. To be specific, the display IC 50 supplies a display drive signal VCOM to the drive electrodes Tx in display. The display IC 50 includes at least a drive signal supply circuit 56. The drive signal supply circuit 56 supplies a detection drive signal VD to the drive electrodes Tx sequentially.

To be specific, in touch detection of detecting the position of the finger Fg, the display IC 50 (drive signal supply circuit 56) supplies the detection drive signal VD to the drive electrodes Tx, and the detection signals Vdet based on the change in the mutual electrostatic capacitances are output to the detection IC 51. The detection IC 51 thereby detects contact or proximity of the finger Fg.

In detection of the input support device 3, the display IC 50 (drive signal supply circuit 56) supplies the detection drive signal VD to the drive electrodes Tx, and the detection IC 51 detects a position and the like of the input support device 3 using the change in the mutual electrostatic capacitances and resonance of the LC circuit 35 included in the input support device 3.

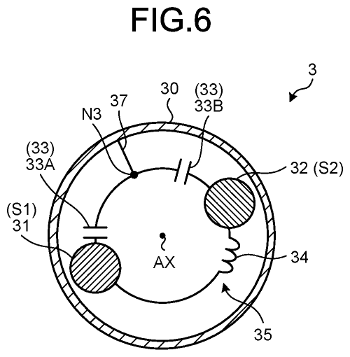

Next, a method for detecting the input support device 3 will be described with reference to FIG. 6 to FIG. 8. FIG. 6 is a cross-sectional view cut along line VI-VI′ in FIG. 2. FIG. 6 schematically illustrates the cross-sectional view provided by cutting the input support device 3 along a plane parallel with the upper surface 111a (see FIG. 1). The input support device 3 has a circular shape in a plan view as illustrated in FIG. 6. The first electrode 31 and the second electrode 32 are arranged on the opposite sides with the rotating axis AX interposed therebetween in a plan view. The first electrode 31 and the second electrode 32 have circular shapes in a plan view. Their shapes are, however, not limited thereto, and the first electrode 31 and the second electrode 32 may have another shape such as a square shape or a polygonal shape. The first electrode 31 and the second electrode 32 may have different shapes.

The capacitor 33 included in the LC circuit 35 includes a first capacitor 33A and a second capacitor 33B coupled in series. A coupling portion N3 between the first capacitor 33A and the second capacitor 33B is coupled to the housing 30 through a coupling member 37. FIG. 6 equivalently illustrates the capacitor 33 and the inductor 34 configuring the LC circuit 35, and, for example, the LC circuit 35 may be formed by a chip component mounted on a substrate. It is sufficient that the capacitor 33 and the inductor 34 are coupled electrically in parallel between the first electrode 31 and the second electrode 32, and arrangement thereof in the housing 30 may be desirably set.

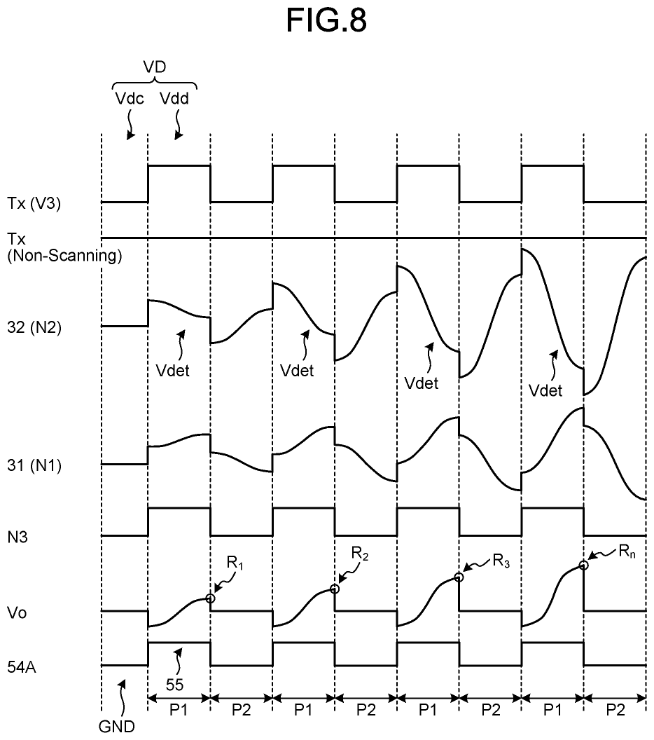

FIG. 7 is a descriptive view for explaining a method for detecting the input support device. FIG. 8 is a timing waveform chart for explaining the method for detecting the input support device. As illustrated in FIG. 7, the first electrode 31 of the input support device 3 is coupled to the coupling portion N1 of the LC circuit 35 on the one end side, and is arranged so as to face the drive electrode Tx of the array substrate SUB1 and the detection electrode Rx of the counter substrate SUB2. The second electrode 32 is coupled to the coupling portion N2 of the LC circuit 35 on the other end side, and is arranged so as to face the drive electrode Tx of the array substrate SUB1 and the detection electrode Rx of the counter substrate SUB2.

In the LC circuit 35, the first capacitor 33A and the second capacitor 33B are coupled in series in this order, between the coupling portion N1 on the one end side and the coupling portion N2 on the other end side of the LC circuit 35. The inductor 34 is coupled in parallel with the first capacitor 33A and the second capacitor 33B coupled in series. The coupling portion N3 between the first capacitor 33A and the second capacitor 33B is coupled to the housing 30 through the coupling member 37. The coupling member 37 is, for example, wiring formed by a conductor. Any shape and configuration of the coupling member 37 may be employed as long as the coupling member 37 can electrically couple the coupling portion N1 and the housing 30. The LC circuit 35 may have a resistive component such as the inductor 34, and may also have additional resistive elements in addition to the first capacitor 33A, the second capacitor 33B, and the inductor 34.

When the operator operates the input support device 3, the finger Fg or the palm thereof comes into contact with the housing 30. The coupling portion N3 between the first capacitor 33A and the second capacitor 33B of the LC circuit 35 is thereby coupled to the reference potential GND through the coupling member 37 and the housing 30. The reference potential GND is, for example, a ground potential. The reference potential GND is, however, not limited thereto and may be a predetermined fixed potential. A configuration in which the outside of the housing 30 is covered with resin or other materials can also be employed. In such a configuration, the housing 30 is capacitively coupled to the finger or the palm that contacts the resin.

The input support device 3 is arranged so as to overlap with a plurality of the drive electrodes Tx and a plurality of the detection electrodes Rx. A capacitance C1 is formed between the first electrode 31 and one of the drive electrodes Tx (the drive electrode Tx on the left in FIG. 7). The one drive electrode Tx is coupled to a reference potential (for example, reference potential Vdc). A capacitance C2 is formed between the second electrode 32 and the other one of the drive electrodes Tx (the drive electrode Tx on the right in FIG. 7). The other drive electrode Tx is coupled to a power supply potential Vdd or to a reference potential (for example, reference potential Vdc) through a switch element 54B.

A capacitance C3 is formed between the second electrode 32 and the detection electrode Rx facing the second electrode 32. The detection electrode Rx is coupled to the detection circuit 55 or the reference potential GND (for example, ground potential) through a switch element 54A. Mutual electrostatic capacitance Cm is further formed between the drive electrode Tx and the detection electrode Rx. A capacitance C4 is formed between the first electrode 31 and the detection electrode Rx facing the first electrode 31.

The detection circuit 55 is a signal processing circuit provided in a detection IC 51, and receives the detection signal Vdet (see FIG. 8) output from the detection electrode Rx and performs predetermined signal processing thereon to output an output signal Vo. The detection circuit 55 includes a detection signal amplifier 61, a capacitive element 62, and a reset switch 63. The detection circuit 55 is not limited to this configuration and may include an A/D conversion circuit (not illustrated) and the like that converts an analog signal output from the detection signal amplifier 61 into a digital signal.

As illustrated in FIG. 7 and FIG. 8, operation of the switch element 54B supplies the detection drive signal VD, which is an AC square wave, to the other drive electrode Tx. To be more specific, the switching operation of the switch element 54B alternately applies the power supply potential Vdd as a high-level potential and the reference potential Vdc as a low-level potential repeatedly at a predetermined frequency, forming the detection drive signal VD and supplying it to the other drive electrode Tx. A potential V3 of the other drive electrode Tx varies in accordance with the detection drive signal VD. Periods that are repeated in synchronization with the detection drive signal VD are first periods P1 and second periods P2. Each of the first periods P1 is a period in which the other drive electrode Tx is coupled to the power supply potential Vdd (a period in which the switch element 54B couples the other drive electrode Tx to the power supply potential Vdd). Each of the second periods P2 is a period in which the other drive electrode Tx is coupled to the reference potential Vdc (a period in which the switch element 54B couples the other drive electrode Tx to the reference potential (ground potential)). The power supply potential Vdd is higher than the reference potential Vdc, for example.

The detection electrode Rx outputs the detection signal Vdet based on the mutual electrostatic capacitance Cm. To be specific, as described above, the one drive electrode Tx is coupled to the reference potential (for example, reference potential Vdc) in both the first period P1 and the second period P2. In the first period P1, signals of different potentials are thereby supplied to the first electrode 31 and the second electrode 32. In the first period P1, the detection electrode Rx is coupled to the detection circuit 55 by the switching operation of the switch element 54A. With this coupling, variation in potential based on the mutual electrostatic capacitance Cm is output as the detection signal Vdet from the detection electrode Rx to the detection circuit 55. In the second period P2, the coupling between the detection electrode Rx and the detection circuit 55 is cut off by the switching operation of the switch element 54A. In the second period P2, the detection electrode Rx is coupled to the reference potential (or ground potential GND) by the switching operation of the switch element 54A.

The detection signal amplifier 61 of the detection circuit 55 amplifies the detection signal Vdet supplied from the detection electrode Rx. Reference voltage having a fixed potential is input to a non-inversion input portion of the detection signal amplifier 61, and the detection electrode Rx is coupled to an inversion input terminal thereof. In the embodiment, the same signal as the signal of the one drive electrode Tx is input as the reference voltage. The detection circuit 55 can reset a charge of the capacitive element 62 by turning the reset switch 63 ON.

The detection drive signal VD has the same frequency as the resonant frequency of the LC circuit 35. In this example, for example, the detection drive signal VD having a resonant frequency is formed by performing the switching operation of the switch element 54B based on the resonant frequency. Accordingly, the second electrode 32 overlapping with the other drive electrode Tx is also driven at the resonant frequency, and the resonance of the LC circuit 35 is generated. With this resonance, as the first periods P1 and the second periods P2 are repeated, the amplitude of the detection signal Vdet is increased. As illustrated in FIG. 8, as a plurality of the first periods P1 are repeated, the amplitude of the detection signal Vdet is increased, so that the potential of the output signal Vo from the detection circuit 55 varies to be increased.

On the other hand, when an object to be detected such as the finger Fg differing from the input support device 3 comes into contact with or close to the upper surface 111a (see FIG. 1), the detection signal Vdet varies in accordance with change in the mutual electrostatic capacitance Cm. That is to say, since no resonance is generated in the case of the finger Fg or the like, variation in the amplitude of the detection signal Vdet over time as illustrated in FIG. 8 does not occur. The input detection system 1 can thus determine whether the object to be detected is the finger Fg or the input support device 3 using the LC resonance of the LC circuit 35.

As illustrated in FIG. 8, the phase of the potential of the first electrode 31 presents a tendency reversed from the phase of the potential of the second electrode 32. That is to say, the coupling portion N1 of the LC circuit 35 on the one end side and the coupling portion N2 of the LC circuit 35 on the other end side have reversed phases of potential. To be specific, the potential of the first electrode 31 tends to be increased and the potential of the second electrode 32 tends to be decreased in each first period P1. The potential of the first electrode 31 tends to be decreased and the potential of the second electrode 32 tends to be increased in each second period P2.

The coupling portion N3 between the first capacitor 33A and the second capacitor 33B does not generate any variation in potential due to the resonance of the LC circuit 35. In other words, as the first periods P1 and the second periods P2 are repeated, the amplitude of the detection signals Vdet of the first electrode 31 and the second electrode 32 increases, while the voltage waveform at the coupling portion N3 has a constant amplitude.

The LC circuit 35 is shielded by the housing 30 as described above. Furthermore, since the housing 30 is coupled to the coupling portion N3, the coupling portion N3 and the housing 30 are coupled to the reference potential when the finger Fg or the palm contacts the housing 30 of the input support device 3 as described above. This configuration can suppress change in the capacitance formed on the LC circuit 35 side even when parasitic capacitance is formed between the housing 30 and the outside (for example, an operator's finger Fg or palm). The capacitance formed on the LC circuit 35 side includes the capacitance formed between the first electrode 31 and the coupling portion N3, and the capacitance formed between the second electrode 32 and the coupling portion N3. Thus, the input support device 3 can mitigate variation in the resonant frequency of the LC circuit 35 even when parasitic capacitance is formed between the housing 30 and the finger Fg or the like. As a result, a decrease in the detection signal Vdet caused by a change in the resonant frequency of the LC circuit 35 can be suppressed, and the detection accuracy of the input support device 3 can be improved. Alternatively, since changes in the resonant frequency of the LC circuit 35 can be suppressed, correction of the drive frequency of the detection drive signal VD is not necessary, and the circuit configuration of the display IC 50 including the drive signal supply circuit 56 can be simplified.

The ratio of a capacitance value CA of the first capacitor 33A to a capacitance value CB of the second capacitor 33B is equal to the ratio of an area S1 of the first electrode 31 (see FIG. 6) to an area S2 of the second electrode 32 (see FIG. 6). In other words, the capacitance value CA of the first capacitor 33A and the capacitance value CB of the second capacitor 33B satisfy the relation in Equation (1) below.

CA:CB=S1:S2 (1)

In other words, the ratio of the capacitance value CA of the first capacitor 33A to the capacitance value CB of the second capacitor 33B is equal to the ratio of an interelectrode capacitance CE1 (the total capacitance value of the capacitance C1 and the capacitance C4) formed between the first electrode 31 and a plurality of electrodes (drive electrode Tx and detection electrode Rx) facing the first electrode 31 to an interelectrode capacitance CE2 (the total capacitance value of the capacitance C2 and the capacitance C3) formed between the second electrode 32 and a plurality of electrodes (drive electrode Tx and detection electrode Rx) facing the second electrode 32. In other words, the capacitance value CA of the first capacitor 33A and the capacitance value CB of the second capacitor 33B satisfy the relation in Equation (2) below.

CA:CB=CE1:CE2 (2)

When the first capacitor 33A and the second capacitor 33B satisfy the relation in Equation (1) or Equation (2), the input support device 3 can suppress the change in potential at the coupling portion N3 due to the resonance of the LC circuit 35.

The width of the drive electrode Tx is smaller than the distance between the first electrode 31 and the second electrode 32 that are placed opposite each other across the rotation axis AX. Thus, the first electrode 31 and the second electrode 32 are arranged overlapping with different drive electrodes Tx, and the drive electrode Tx overlapping with the first electrode 31 (the one drive electrode Tx) is supplied with the reference potential Vdc, and the drive electrode Tx overlapping with the second electrode 32 (the other drive electrode Tx) is supplied with the detection drive signal VD. As a result, the second electrode 32 can increase the amplitude of the detection signal Vdet using the resonance of the resonance of the LC circuit 35.

The drive signal supply circuit 56 may supply the detection drive signal VD to a plurality of adjacent drive electrodes Tx simultaneously, and drive each drive electrode block consisting of a plurality of adjacent drive electrodes Tx. The drive electrode Tx supplied with the detection drive signal VD from the drive signal supply circuit 56 changes accordingly in a time-divisional manner. For example, in the predetermined first detection period, the above-mentioned other drive electrode Tx is coupled to the drive signal supply circuit 56, and in the next second detection period, the coupling between the other drive electrode Tx and the drive signal supply circuit 56 is cut off, and the drive electrode Tx next to the other drive electrode Tx is coupled to the drive signal supply circuit 56. These drive electrodes Tx also function as the common electrodes of the display device. If that period is referred to as a display period, the display period may be provided between the first detection period and the second detection period, or a configuration may be employed in which the second detection period is provided immediately after the first detection period, followed by the display period. When there are N drive electrodes Tx, and the above-mentioned other drive electrode Tx is driven in the first detection period, the drive electrode Tx next to the other drive electrode Tx in the second detection period, the drive electrode Tx that is two electrodes away from the other drive electrode Tx in the third detection period, and the Nth drive electrode Tx in the Nth period, and so on, the display period may be provided after the Nth detection period from the first detection period. A configuration can also be adopted in which the first to the Nth detection periods are divided into multiple periods and the display period is provided between those periods. As for the display period, a configuration in which display in the entire display area is refreshed in the display period can be adopted, or a configuration in which a portion of the display area is refreshed in the display period can be adopted.

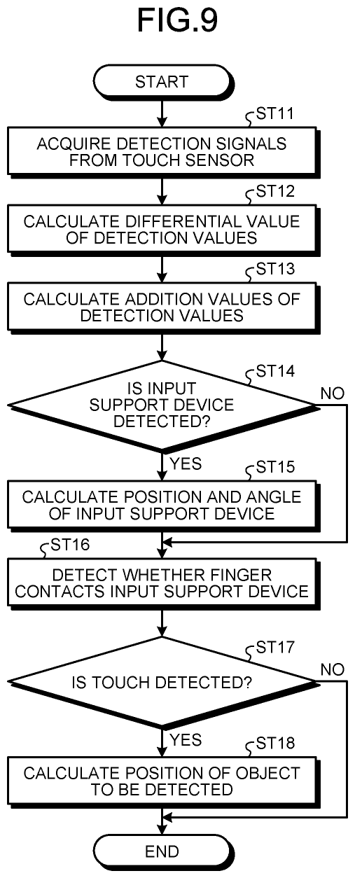

Next, a method for detecting the input support device 3 and an object to be detected such as the finger Fg or the like, which is different from the input support device 3, in the input detection system 1, is described. FIG. 9 is a flowchart for explaining a detection method in the input detection system. First, the detection circuit 55 acquires the detection signals Vdet from a touch sensor including the drive electrodes Tx and the detection electrodes Rx (step ST11). The detection circuit 55 performs signal processing on the detection signals Vdet and outputs the output signals Vo containing a plurality of detection values R (R₁, R₂, R₃, . . . , and Rₙ (see FIG. 8)) to a calculation circuit (not illustrated) included in the detection IC 51. The detection values R₁, R₂, R₃, . . . , and Rₙ are pieces of data provided by sampling from the analog signal output from the detection signal amplifier 61 at timings in synchronization with the detection drive signal VD.

Then, the calculation circuit calculates a differential value of at least two detection values R based on the output signals Vo received from the detection circuit 55 (step ST12). The calculation circuit may divide the detection values R₁, R₂, R₃, . . . , and Rₙ into two groups to calculate a difference between the total of one group of the detection values R and the total of the other group of the detection values R, for example.

Subsequently, the calculation circuit calculates addition values of at least two detection values R based on the output signals Vo received from the detection circuit 55 (step ST13). The calculation circuit may calculate an addition value by summing up the detection values R₁, R₂, R₃, . . . , and Rₙ, for example.

The calculation circuit determines whether the input support device 3 is detected (step ST14). To be specific, the calculation circuit compares the differential values acquired at step ST12 and a first detection reference value previously stored in a storage circuit. When any of the differential values is equal to or larger than the first detection reference value, that is, when the input support device 3 is detected (Yes at step ST14), the calculation circuit calculates the position of the input support device 3 and the angle (rotation operation RT) of the input support device 3 (step ST15).

Then, the calculation circuit detects whether the finger Fg contacts the input support device 3 (step ST16). As described above, the input support device 3 is shielded by the coupling portion N3, and thus the amplitude of the detection signal Vdet does not change even if parasitic capacitance is formed between the housing 30 and, for example, the operator's finger Fg or palm. In other words, even if parasitic capacitance is formed between the housing 30 and the finger Fg, the voltage applied between the coupling portion N1 of the LC circuit 35 on the one end side and the coupling portion N2 of the LC circuit 35 on the other end side will not change. Therefore, the increase in the amplitude of the detection signal Vdet (see FIG. 8) due to the resonance of the LC circuit 35 will have the same tendency even when external parasitic capacitance is formed. Therefore, the differential values acquired at step ST12 do not change.

On the other hand, if parasitic capacitance is formed between the housing 30 and the finger Fg, the charge supplied to the coupling portion N2 of the LC circuit 35 on the other end side (the capacitance C3 between the second electrode 32 and the detection electrode Rx) will change. In other words, the baseline of the output signal Vo changes. Based on the difference of the baseline, the calculation circuit can detect whether the finger Fg has made contact with the input support device 3. Therefore, the calculation circuit can detect the contact of the finger Fg with the input support device 3 based on a signal (baseline difference) that is different from the detection values R₁, R₂, R₃, . . . , Rₙ, without affecting the detection of the input support device 3.

Then, the calculation circuit determines whether touch of the object to be detected such as the finger Fg is detected (step ST17). To be specific, the calculation circuit compares the addition values acquired at step ST13 and a second detection reference value previously stored in the storage circuit. When any of the addition values is equal to or larger than the second detection reference value, that is, when touch of the object to be detected such as the finger Fg is detected (Yes at step ST17), the calculation circuit calculates the position of the object to be detected such as the finger Fg (step ST18).

When the addition values are smaller than the second detection reference value, that is, when touch of the object to be detected such as the finger Fg is not detected (No at step ST17), the calculation circuit omits calculation of the position of the object to be detected such as the finger Fg. The calculation circuit outputs calculation results (information related to the input support device 3 and touch detection information of the finger Fg or the like) to an external host IC and finishes detection for one frame.

The detection method illustrated in FIG. 9 is merely an example and can be appropriately modified. For example, the detection IC 51 may perform the detection of the input support device 3 (steps ST12, ST14, and ST15) and the touch detection of the finger Fg or the like (steps ST13, ST16, and ST17) simultaneously.

As described above, the input detection system 1 includes the electrodes (drive electrodes Tx and detection electrodes Rx) arrayed in the detection region (display region DA), and the input support device 3 including the LC circuit 35, the first electrode 31 coupled to the one end side of the LC circuit 35, the second electrode 32 coupled to the other end side of the LC circuit 35, and the housing 30 accommodating therein at least the LC circuit 35. The input support device 3 is disposed overlapping with the electrodes (drive electrodes Tx and detection electrodes Rx), the housing 30 is a conductor, the LC circuit 35 includes the first capacitor 33A and the second capacitor 33B coupled in series between the one end side and the other end side of the LC circuit 35, and the coupling portion N3 between the first capacitor 33A and the second capacitor 33B is coupled to the housing 30.

In this way, the LC circuit 35 of the input support device 3 is shielded by the coupling portion N3 and the housing 30. Furthermore, since the housing 30 is coupled to the coupling portion N3, the coupling portion N3 and the housing 30 are coupled to the reference potential when the finger Fg or the palm contacts the housing 30 of the input support device 3 as described above. This can suppress change in the resonant frequency of the LC circuit 35 even when parasitic capacitance is formed between the housing 30 and the outside (for example, the operator's finger Fg or palm). Since the input detection system 1 can suppress the change in the resonant frequency of the LC circuit 35, the correction of the drive frequency of the detection drive signal VD is unnecessary, and the circuit configuration of the display IC 50 including the drive signal supply circuit 56 can be simplified.

### First Modification

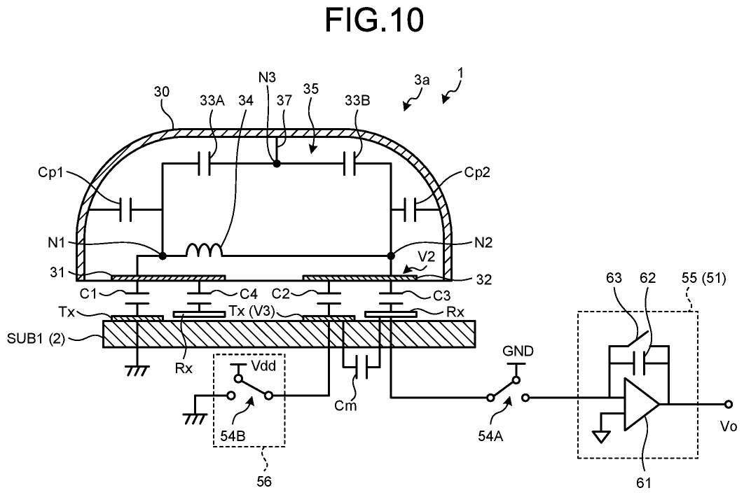

FIG. 10 is a descriptive view for explaining an input support device according to a first modification. In the following explanation, the same reference numerals denote the same components described in the above-mentioned embodiment and overlapped explanation thereof is omitted.

In the first embodiment described above, parasitic capacitances Cp1 and Cp2 formed in the LC circuit 35 are omitted for the sake of clarity of explanation. In the input support device 3a of the first modification, the capacitance value CA of the first capacitor 33A and the capacitance value CB of the second capacitor 33B are explained when the parasitic capacitances Cp1 and Cp2 are considered, as illustrated in FIG. 10. The parasitic capacitance Cp1 is parasitic capacitance formed between the one end side of the LC circuit 35 (coupling portion N1) and the housing 30. The parasitic capacitance Cp2 is parasitic capacitance formed between the other end side of the LC circuit 35 (coupling portion N2) and the housing 30.

In the first modification, the capacitance value CA of the first capacitor 33A and the capacitance value CB of the second capacitor 33B satisfy the relation in Equation (2) below.

CA+Cp1:CB+Cp2=CE1:CE2 (3)

However, the interelectrode capacitances CE1 and CE2 are the same as those in the first embodiment described above. The interelectrode capacitance CE1 is the capacitance value formed in the first electrode 31 (the total capacitance value of the capacitance C1 and the capacitance C4), and the interelectrode capacitance CE2 is the capacitance value formed in the second electrode 32 (the total capacitance value of the capacitance C2 and the capacitance C3).

Considering the parasitic capacitances Cp1 and Cp2, when the first capacitor 33A and the second capacitor 33B satisfy the relation in Equation (3), the input support device 3a can suppress change in potential due to resonance of the LC circuit 35 at the coupling portion N3. Equation (3) present the ratio of the interelectrode capacitance CE1 to the interelectrode capacitance CE2; however, it can also presents the ratio of the area S1 of the first electrode 31 to the area S2 of the second electrode 32, as in Equation (1) above.

### Second Modification

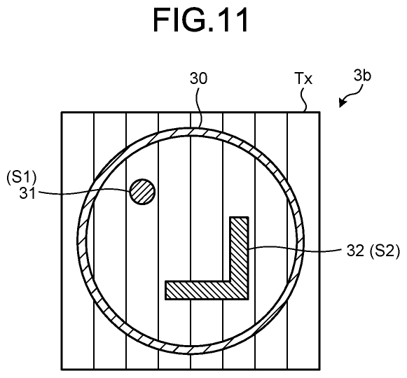

FIG. 11 is a plan view schematically illustrating an input support device according to a second modification.

In the first embodiment and the first modification described above, a configuration is described in which the shape and the area S1 of the first electrode 31 are the same as the shape and the area S2 of the second electrode 32; however, the shape and the area are not limited thereto. The following describes a configuration in which the shapes of the first electrode 31 and the second electrodes 32 are different in an input support device 3b of the second modification.

As illustrated in FIG. 11, the first electrode 31 has a circular shape in a plan view and is arranged so as to overlap with one drive electrode Tx. The second electrode 32 has an L shape and is arranged so as to overlap with three drive electrodes Tx. In a plan view, the area S2 of the second electrode 32 is larger than the area S1 of the first electrode 31. In this modification, the first capacitor 33A and the second capacitor 33B can be designed by applying any of the above Equations (1) to (3).

Since the shape and the area S1 of the first electrode 31 are different from the shape and the area S2 of the second electrode 32, even when the first electrode 31 and the second electrode 32 are placed side by side along an extension direction of the drive electrodes Tx by a rotation operation of the input support device 3b, at least a part of the second electrode 32 overlaps with a drive electrode Tx that is different from the drive electrode Tx overlapping with the first electrode 31. Therefore, the input detection system 1 can supply signals of different potentials to the first electrode 31 and the second electrode 32, regardless of the direction of rotation of the input support device 3b.

The first electrode 31 and the second electrode 32 are not limited to circular or L-shaped, and other shapes can be adopted. For example, the first electrode 31 and the second electrode 32 may be elliptical, oval, rectangular, polygonal, or another shape.

### Second Embodiment

The above-described first embodiment, first modification, and second modification describe examples of the input support device 3 arranged above the mutual electrostatic capacitance type touch sensor (display device 2) including the drive electrodes Tx and the detection electrodes Rx; however, the disclosure is not limited thereto. The touch sensor (display device 2) may be of self electrostatic capacitance type (self type).

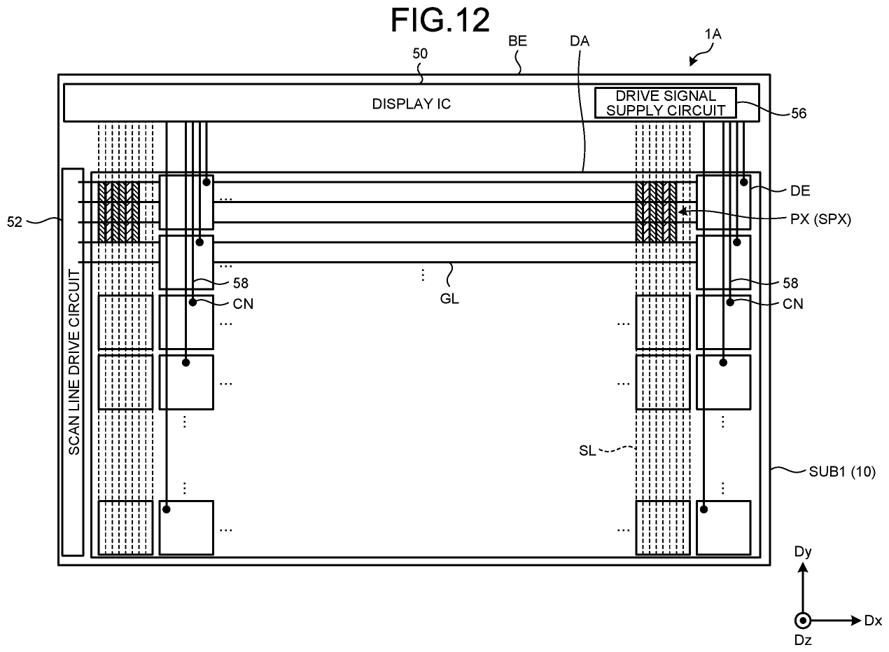

FIG. 12 is a plan view schematically illustrating an array substrate in an input detection system according to a second embodiment. As illustrated in FIG. 12, in an input detection system 1A of the second embodiment, the array substrate SUB1 includes a plurality of detection electrodes DE. The detection electrodes DE are arrayed in a matrix with a row-column configuration in the display region DA.

Sensor wiring lines 58 are provided so as to correspond to the respective detection electrodes DE and are coupled to the detection electrodes DE through contact holes CN. The sensor wiring lines 58 extend along the second direction Dy and are aligned in the first direction Dx. The sensor wiring lines 58 and the pixel signal lines SL are coupled to the display IC 50 provided in the peripheral region BE.

The detection electrodes DE serve as common electrodes in display and the drive electrodes Tx and the detection electrodes Rx for detecting the input support device 3 and an object to be detected such as a finger Fg. The display IC 50 may also have the functions of the detection IC 51 illustrated in FIG. 9 and other drawings. Alternatively, the detection IC 51 may be provided separately from the display IC 50.

The display IC 50 supplies the display drive signal VCOM to the detection electrodes DE in display. In the detection of an object to be detected such as the input support device 3 or the finger Fg, the drive signal supply circuit 56 of the display IC 50 supplies the detection drive signal VD to the detection electrodes DE through the sensor wiring lines 58. The detection electrodes DE output the detection signals Vdet through the sensor wiring lines 58 based on the change in the self electrostatic capacitances of the detection electrodes DE and the resonance of the LC circuit 35. The display IC 50 (or detection IC 51) detects the input support device 3 or an object to be detected such as the finger Fg based on the detection values R (output signals Vo) obtained by signal processing on the detection signals Vdet.

In the self electrostatic capacitance type touch detection, the touch sensor (display device 2) can detect the finger Fg or the like by supplying detection drive signal VD to all detection electrodes DE. On the other hand, in the detection of the input support device 3, the detection drive signal VD is sequentially supplied to the detection electrodes DE so as to generate the resonance of the LC circuit 35.

Although the preferred embodiments of the present disclosure have been described above, the present disclosure is not limited to these embodiments. Contents disclosed in the embodiments are merely examples, and various modifications can be made in a range without departing from the gist of the present disclosure. It is needless to say that appropriate modifications in a range without departing from the gist of the present disclosure belong to the technical scope of the present disclosure.

At least one of various omission, replacement, and modification of the components can be performed in a range without departing from the gist of the embodiments and modifications described above.

What is claimed is:

1. An input detection system comprising:
a plurality of electrodes arrayed in a detection region; and
an input support device including an LC circuit, a first electrode coupled to one end side of the LC circuit, a second electrode coupled to another end side of the LC circuit, and a housing accommodating therein at least the LC circuit, wherein
the input support device is disposed overlapping with a plurality of the electrodes,
the housing is a conductor,
the LC circuit includes a first capacitor and a second capacitor coupled in series between the one end side and the other end side of the LC circuit, and
a coupling portion between the first capacitor and the second capacitor is coupled to the housing.

2. The input detection system according to claim 1, wherein
a ratio of a capacitance value of the first capacitor to a capacitance value of the second capacitor satisfies a relation in Equation (1) below:
CA:CB=S1:S2 (1),
where CA is the capacitance value of the first capacitor, CB is the capacitance value of the second capacitor, S1 is an area of the first electrode, and S2 is an area of the second electrode.

3. The input detection system according to claim 1, wherein
a ratio of a capacitance value of the first capacitor to a capacitance value of the second capacitor satisfies a relation in Equation (2) below:
CA:CB=CE1:CE2 (2),
where CA is the capacitance value of the first capacitor, CB is the capacitance value of the second capacitor, CE1 is interelectrode capacitance formed between the first electrode and a plurality of the electrodes facing the first electrode, and CE2 is interelectrode capacitance formed between the second electrode and a plurality of the electrodes facing the second electrode.

4. The input detection system according to claim 1, wherein
a ratio of a capacitance value of the first capacitor to a capacitance value of the second capacitor satisfies a relation in Equation (3) below:
CA+Cp1:CB+Cp2=CE1:CE2 (3),
where CA is the capacitance value of the first capacitor, CB is the capacitance value of the second capacitor, Cp1 is a capacitance value of parasitic capacitance formed on the one end side of the LC circuit, Cp2 is a capacitance value of parasitic capacitance formed on the other end side of the LC circuit, CE1 is a capacitance value of interelectrode capacitance formed between the first electrode and a plurality of the electrodes facing the first electrode, and CE2 is a capacitance value of interelectrode capacitance formed between the second electrode and a plurality of the electrodes facing the second electrode.

5. The input detection system according to claim 1, wherein the coupling portion of the LC circuit is coupled to a reference potential through the housing.

6. The input detection system according to claim 1, wherein
the electrode overlapping with one of the first electrode and the second electrode is supplied with a reference potential, and
the electrode overlapping with another of the first electrode and the second electrode is supplied with a detection drive signal.

7. An input support device comprising:
an LC circuit;
a first electrode coupled to one end side of the LC circuit;
a second electrode coupled to another end side of the LC circuit; and
a housing accommodating therein at least the LC circuit, wherein
the housing is a conductor,
the LC circuit includes a first capacitor and a second capacitor coupled in series between the one end side and the other end side of the LC circuit, and
a coupling portion between the first capacitor and the second capacitor is coupled to the housing.
